(19) United States
(12) Patent Application Publication
(10) Pub. No.: US 2009/0085082 A1
(43) Pub. Date: Apr. 2, 2009

(54) CONTROLLED INTERMIXING OF HFO2 AND ZRO2 DIELECTRICS ENABLING HIGHER DIELECTRIC CONSTANT AND REDUCED GATE LEAKAGE

(76) Inventors: Gilbert Dewey, Hillsboro, OR (US); Matthew Metz, Hillsboro, OR (US); Jack Kavalieros, Portland, OR (US); Robert Chau, Beaverton, OR (US)

Correspondence Address: COOL PATENT, P.C.;c/o CPA Global, P.O. BOX 52050, MINNEAPOLIS, MN, 55402, US

(21) Appl. No.: 11/863,211

(22) Filed: Sep. 27, 2007

(51) Int. Cl. H01L 29/94; H01L 23/58; H01L 21/8242; H01L 21/31

(52) U.S. Cl. 257/297; 257/632; 438/785; 438/239; 257/E29.345; 257/E23.001; 257/E21.646; 257/E21.24

(57) ABSTRACT

Controlled deposition of HfO₂ and ZrO₂ dielectrics is generally described. In one example, a microelectronic apparatus includes a substrate and a dielectric film coupled with the substrate, the dielectric film including ZrO₂ and HfO₂ wherein the ratio of Zr to Hf in the dielectric film is about 5 to 10 atoms of Zr for every 1 atom of Hf to reduce ToxE or reduce Jox of the dielectric film.

### BACKGROUND

Generally, semiconductor devices utilize dielectric materials to electrically insulate a variety of electrically conductive microstructures.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 is a schematic of a dielectric stack in a microelectronic device, according to but one embodiment;

FIG. 2 is a graph of Jox and ToxE for several dielectric films, according to but one embodiment;

FIG. 3 is flow diagram for forming a dielectric stack, according to but one embodiment; and

FIG. 4 is a diagram of an example system in which embodiments of the present invention may be used, according to but one embodiment.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of controlled deposition of HfO₂ and ZrO₂ dielectrics are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

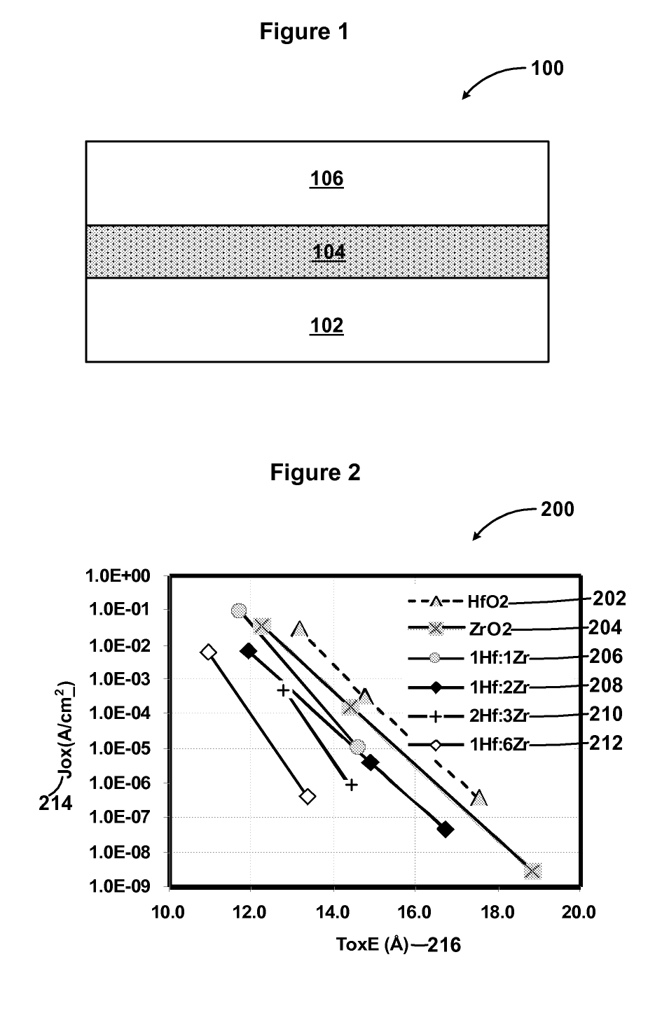

FIG. 1 is a schematic of a dielectric stack in a microelectronic device 100, according to but one embodiment. In an embodiment, a microelectronic apparatus 100 includes a substrate 102, a dielectric film 104 including HfO₂ and ZrO₂, and an electrically conductive material or film 106, each coupled as shown. In an embodiment, an electrically conductive material 106 is a material that is more electrically conductive than dielectric film 104.

In an embodiment, a microelectronic apparatus 100 includes a substrate 102 and a dielectric film 104 coupled with the substrate, the dielectric film 104 including ZrO₂ and HfO₂ wherein the ratio of Zr to Hf in the dielectric film is about 5 to 10 atoms of Zr for every 1 atom of Hf. In an embodiment, a ratio of about 5 to 10 atoms of Zr for every 1 atom of Hf at least includes about 6 atoms of Zr for every 1 atom of Hf in the dielectric film 104. Such ratio of the Zr and Hf components of the dielectric film 104 may reduce the equivalent dielectric (i.e. —oxide) thickness (ToxE) or reduce the dielectric current density (Jox) of the dielectric film 104. Such benefit may enable a thinner dielectric film 104 or reduce current leakage in a microelectronic device 100.

In an embodiment, a dielectric film 104 as described above may increase dielectric constant in a gate oxide enabling effective electrical gate oxide thinning without an increase in gate leakage, which may be advantageous for scaling in memory or logic applications. Combination of ZrO₂ and HfO₂ may also enable a dielectric 104 that is more amorphous than the pure films alone. A more amorphous dielectric film 104 structure may be desired because a crystalline dielectric may have leakage paths along crystal grain boundaries resulting in higher oxide leakage for a given thickness compared to an amorphous dielectric.

In an embodiment, a combination of ZrO₂ and HfO₂ wherein the ratio of Zr to Hf in the dielectric film 104 is about 6 atoms of Zr for every 1 atom of Hf provides a Jox or ToxE that is lower than for pure ZrO₂ films, pure HfO₂ films, or combinations of ZrO₂ and HfO₂ in different ratios. In another embodiment, a dielectric film 104 having a ratio for ZrO₂ and HfO₂ of about 6 atoms of Zr for every 1 atom of Hf provides a higher dielectric constant k, and/or reduced current leakage over pure ZrO₂ films, pure HfO₂ films, or combinations of ZrO₂ and HfO₂ in different ratios.

A dielectric film 104 including HfO₂ and ZrO₂ may be deposited by a variety of suitable deposition techniques. In an embodiment, a dielectric film 104 is deposited using atomic layer deposition (ALD), physical vapor deposition (PVD), chemical vapor deposition (CVD), sputtering, or any suitable combination thereof. In an embodiment, a dielectric film 104 is deposited by ALD using 6 cycles of ZrO₂ deposition for every 1 cycle of HfO₂ deposition. Such deposition ratio may be repeated until a desired thickness is achieved. Such deposition can be accomplished in any order or simultaneously.

A cycle may refer to a series of actions associated with depositing a dielectric film 104. In a gas flow embodiment, a cycle includes applying a precursor gas (i.e.—ZrCl₄) having a desired metal such as Zr or Hf to the substrate, purging the substrate surface with an inert gas, oxidizing the Zr or Hf on the substrate, and purging the substrate surface again with an inert gas. In an embodiment, purging with an inert gas is accomplished using nitrogen. In another embodiment, oxidizing the Zr or Hf is accomplished using steam.

In another embodiment, Zr and/or Hf precursors are flowed at the same time, but in different flow ratios to achieve a desired ratio in the film such as about 6 Zr atoms for every 1 Hf atom. In another embodiment, the precursors are compatible (i.e.—ZrCl₄ and HfCl₄) such that they may co-flow, which may save recipe time and increase throughput.

A dielectric film 104 including a ratio of about 6:1 of ZrO₂ to HfO₂ may improve dielectric films in a variety of microelectronic devices and/or applications. In an embodiment, a dielectric film 104 that accords with embodiments described herein is used in a capacitor or transistor of memory or logic applications.

The substrate 102 may include a variety of materials, features, films, or elements. In an embodiment, a substrate 102 includes a first electrode 102 coupled with the dielectric film 104. In an embodiment, the electrically conductive material 106 includes a second electrode wherein the first electrode 102, the dielectric film 104, and the second electrode 106 are coupled together. In another embodiment, the first electrode 102, the dielectric film 104, and the second electrode 106 are part of a metal-insulator-metal (MIM) capacitor for a memory device. In such embodiment, the dielectric film 104 may enable smaller capacitor area need to store charge.

In another embodiment, a substrate 102 includes a semiconductor 102 coupled with the dielectric film 104. An electrically conductive material 106 may also be coupled with the dielectric film 104 wherein the semiconductor 102, the dielectric film 104, and the electrically conductive material 106 are coupled together. The semiconductor 102, dielectric film 104, and electrically conductive material 106 may be part of a metal-oxide-semiconductor (MOS) transistor for a logic device. In an embodiment, the dielectric film 104 is a gate dielectric. In such embodiment, the dielectric film 104 may reduce gate leakage, improve channel control, provide higher drive currents, and/or enable physical gate length scaling, or suitable combinations thereof.

FIG. 2 is a graph of Jox and ToxE for several dielectric films 200, according to but one embodiment. In an embodiment, graph 200 includes Jox 214 and ToxE 216 for pure HfO₂ 202, pure ZrO₂ 204, and combinations of HfO₂ and ZrO₂ at ratios of 1Hf:1Zr 206, 1Hf:2Zr 208, 2Hf:3Zr 210, and 1Hf:6Zr 212. Reduced Jox (A/cm²) 214 and ToxE (Angstroms) 216 values may be desirable for a dielectric material or film to reduce the thickness required for a film or to reduce current leakage. In an embodiment, graph 200 includes Jox 214 and ToxE 216 values for a range of about 40-60 angstroms thickness for the represented dielectrics 202, 204, 206, 208, 210, 212.

In an embodiment, a dielectric film including HfO₂ and ZrO₂ at a ratio of about 1Hf:6Zr 212 provides reduced Jox 214 and reduced ToxE 216. ToxE 216 may represent the equivalent thickness of SiO₂ needed to provide similar electrical insulation. Other dielectrics currently used in semiconductor devices other than pure HfO₂ films may be replaced by a combination of HfO₂ and ZrO₂ at a ratio of about 1Hf:6Zr 212.

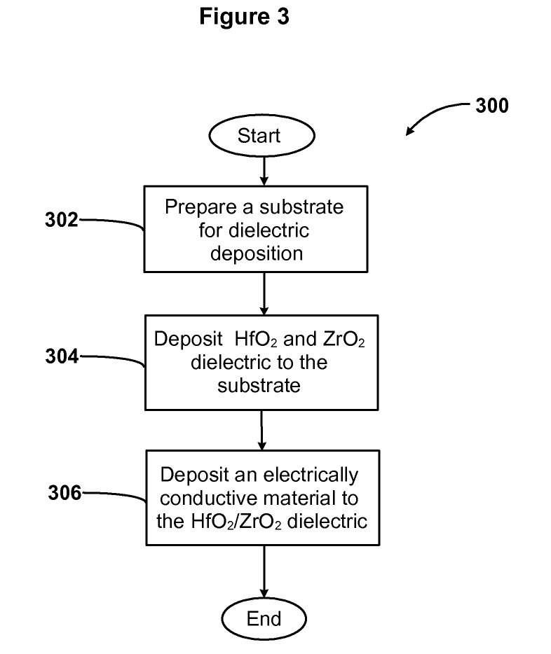

FIG. 3 is flow diagram for forming a dielectric stack 300, according to but one embodiment. In an embodiment, a method 300 includes preparing a substrate for dielectric deposition 302, depositing HfO₂ and ZrO₂ dielectric to the substrate 304, and depositing an electrically conductive material to the HfO₂ and ZrO₂ dielectric 306.

Preparing a substrate for dielectric deposition 302 may include any variety of process steps such as lithography, etch, clean, metrology, diffusion, polish, or other actions associated with semiconductor manufacture to prepare the substrate for dielectric deposition.

In an embodiment, a method 300 includes preparing a substrate for deposition of a dielectric film 302, and depositing ZrO₂ and HfO₂ 304 wherein the ratio of Zr to Hf in the dielectric film is about 5 to 10 atoms of Zr for every 1 atom of Hf to reduce ToxE or reduce Jox of the dielectric film. In an embodiment, a method 300 includes depositing a dielectric 304 having a ratio of ZrO₂ and HfO₂ of about 6 atoms of Zr for every 1 atom of Hf in the dielectric film.

Depositing a dielectric film 304 may be accomplished in a variety of ways. In an embodiment, depositing a dielectric film 304 is accomplished using ALD, PVD, CVD, sputtering, or any suitable combination thereof. A dielectric film may be deposited 304 by ALD using 6 cycles of ZrO₂ deposition for every 1 cycle of HfO₂ deposition. Such ratio of cycles or similar ratio of cycles may be repeated until a desired dielectric thickness is achieved.

In an embodiment, using a cycle includes applying a precursor gas including Zr or Hf to the substrate, purging the substrate surface with an inert gas, oxidizing the Zr or Hf, and purging the substrate surface again with an inert gas. An inert gas may be nitrogen. Oxidation may be accomplished using steam.

A dielectric film in method 300 may be deposited for use in a capacitor or transistor of memory or logic applications, or suitable combinations thereof. In an embodiment, preparing a substrate 302 includes preparing a first electrode 302. A method 300 may include depositing a second electrode 306 to the dielectric film wherein the first electrode, the dielectric film, and the second electrode form part of a metal-insulator-metal (MIM) capacitor for a memory device. In such embodiment, depositing a dielectric film 304 may enable smaller capacitor area needed to store charge. Thinning the overall ToxE of the stack may enable scaling of a memory device. In an embodiment, depositing a dielectric film 304 according to embodiments herein provides a high dielectric constant film to enable dynamic random access memory (DRAM) scaling.

In another embodiment, preparing a substrate 302 includes preparing a semiconductor 302 for dielectric film deposition. A method 300 may include depositing an electrically conductive film 306 to the dielectric film wherein the semiconductor, the dielectric film, and the electrically conductive film form part of a metal-oxide-semiconductor (MOS) transistor for a logic device. In such embodiment, the dielectric film may be a gate dielectric that enables reduced gate leakage, improved channel control, higher drive currents, physical gate length scaling, or suitable combinations thereof.

Various operations may be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

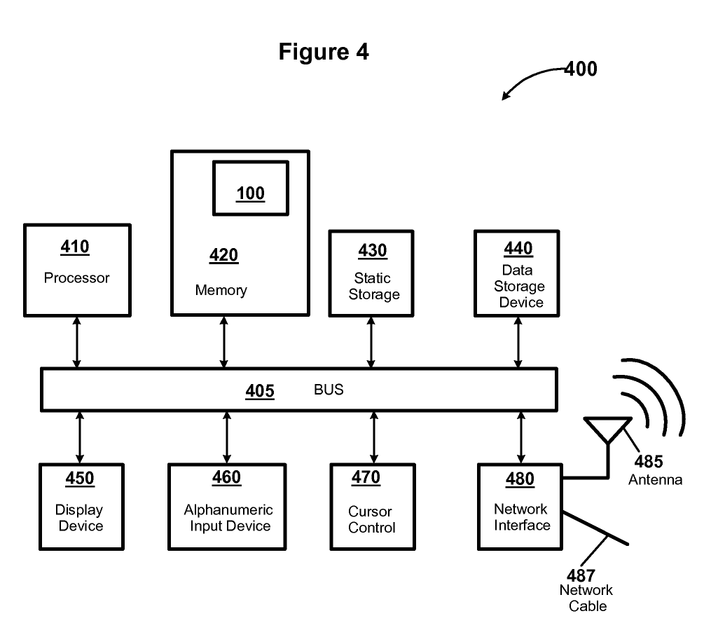

FIG. 4 is a diagram of an example system in which embodiments of the present invention may be used 400, according to but one embodiment. System 400 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

In one embodiment, electronic system 400 includes a semiconductor device or product including HfO₂ and ZrO₂ dielectrics 100 in accordance with embodiments described with respect to FIGS. 1-3. In an embodiment, a semiconductor device or product including HfO₂ and ZrO₂ dielectrics 100 is part of an electronic system's memory 420 or processor 410.

Electronic system 400 may include bus 405 or other communication device to communicate information, and processor 410 coupled to bus 405 that may process information. While electronic system 400 may be illustrated with a single processor, system 400 may include multiple processors and/or co-processors. In an embodiment, processor 410 includes a semiconductor device or product including HfO₂ and ZrO₂ dielectrics 100 in accordance with embodiments described herein. System 400 may also include random access memory (RAM) or other storage device 420 (may be referred to as memory), coupled to bus 405 and may store information and instructions that may be executed by processor 410.

Memory 420 may also be used to store temporary variables or other intermediate information during execution of instructions by processor 410. Memory 420 is a flash memory device in one embodiment. In another embodiment, memory 420 includes a semiconductor device or product including HfO₂ and ZrO₂ dielectrics 100 as disclosed herein.

System 400 may also include read only memory (ROM) and/or other static storage device 430 coupled to bus 405 that may store static information and instructions for processor 410. Data storage device 440 may be coupled to bus 405 to store information and instructions. Data storage device 440 such as a magnetic disk or optical disc and corresponding drive may be coupled with electronic system 400.

Electronic system 400 may also be coupled via bus 405 to display device 450, such as a cathode ray tube (CRT) or liquid crystal display (LCD), to display information to a user. Alphanumeric input device 460, including alphanumeric and other keys, may be coupled to bus 405 to communicate information and command selections to processor 410. Another type of user input device is cursor control 470, such as a mouse, a trackball, or cursor direction keys to communicate information and command selections to processor 410 and to control cursor movement on display 450.

Electronic system 400 further may include one or more network interfaces 480 to provide access to network, such as a local area network. Network interface 480 may include, for example, a wireless network interface having antenna 485, which may represent one or more antennae. Network interface 480 may also include, for example, a wired network interface to communicate with remote devices via network cable 487, which may be, for example, an Ethernet cable, a coaxial cable, a fiber optic cable, a serial cable, or a parallel cable.

In one embodiment, network interface 480 may provide access to a local area network, for example, by conforming to an Institute of Electrical and Electronics Engineers (IEEE) standard such as IEEE 802.11b and/or IEEE 802.11 g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11 g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 480 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 400 includes one more omnidirectional antennae 485, which may refer to an antenna that is at least partially omnidirectional and/or substantially omnidirectional, and a processor 410 coupled to communicate via the antennae.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined entirely by the following claims, which are to be construed in accordance with established doctrines of claim interpretation.

What is claimed is:

1. An apparatus comprising:
a substrate; and
a dielectric film coupled with the substrate, the dielectric film comprising ZrO₂ and HfO₂ wherein the ratio of Zr to Hf in the dielectric film is about 5 to 10 atoms of Zr for every 1 atom of Hf to reduce ToxE or reduce Jox, or combinations thereof, of the dielectric film.

2. An apparatus according to claim 1 wherein the dielectric film is deposited using atomic layer deposition (ALD), physical vapor deposition (PVD), chemical vapor deposition (CVD), sputtering, or any suitable combination thereof.

3. An apparatus according to claim 1 wherein the dielectric film is deposited by atomic layer deposition (ALD) using 6 cycles of ZrO₂ deposition for every 1 cycle of HfO₂ deposition until a desired thickness is achieved.

4. An apparatus according to claim 1 wherein the substrate comprises a first electrode coupled with the dielectric film, the apparatus further comprising:
a second electrode coupled with the dielectric film wherein the first electrode, the dielectric film, and the second electrode are part of a metal-insulator-metal (MIM) capacitor for a memory device wherein the dielectric film allows for a smaller capacitor area needed to store charge.

5. An apparatus according to claim 1 wherein the substrate comprises a semiconductor coupled with the dielectric film, the apparatus further comprising:
an electrically conductive film coupled with the dielectric film wherein the semiconductor, the dielectric film, and the electrically conductive film are part of a metal-oxide-semiconductor (MOS) transistor for a logic device wherein the dielectric film is a gate dielectric that provides for reduced gate leakage, improved channel control, higher drive currents, or physical gate length scaling, or suitable combinations thereof.

6. An apparatus according to claim 1 wherein the ratio is about 6 atoms of Zr for every 1 atom of Hf in the dielectric film.

7. An apparatus according to claim 1 wherein the dielectric film is used in a capacitor or transistor of memory or logic applications, or suitable combinations thereof.

8. A method comprising:
preparing a substrate for deposition of a dielectric film; and
depositing a dielectric film comprising a ZrO₂ and HfO₂ wherein the ratio of Zr to Hf in the dielectric film is about 5 to 10 atoms of Zr for every 1 atom of Hf to reduce ToxE or reduce Jox, or combinations thereof, of the dielectric film.

9. A method according to claim 8 wherein depositing a dielectric film is accomplished using atomic layer deposition (ALD), physical vapor deposition (PVD), chemical vapor deposition (CVD), sputtering, or any suitable combination thereof.

10. A method according to claim 8 wherein depositing a dielectric film is accomplished using atomic layer deposition (ALD) using 6 cycles of ZrO₂ deposition for every 1 cycle of HfO₂ deposition until a desired thickness is achieved.

11. A method according to claim 10 wherein using a cycle comprises:
applying a precursor gas comprising Zr or Hf to the substrate;
purging the substrate surface with an inert gas;
oxidizing the Zr or Hf; and
purging the substrate surface again with an inert gas.

12. A method according to claim 8 wherein the substrate comprises a first electrode, the method further comprising:
depositing a second electrode to the dielectric film wherein the first electrode, the dielectric film, and the second electrode are part of a metal-insulator-metal (MIM) capacitor for a memory device wherein the dielectric film allows for a smaller capacitor area needed to store charge.

13. A method according to claim 8 wherein the substrate comprises a semiconductor, the method further comprising:
depositing an electrically conductive film to the dielectric film wherein the semiconductor, the dielectric film, and the electrically conductive film are part of a metal-oxide-semiconductor (MOS) transistor for a logic device wherein the dielectric film is a gate dielectric that provides for reduced gate leakage, improved channel control, higher drive currents, or physical gate length scaling, or suitable combinations thereof.

14. A method according to claim 8 wherein the ratio is about 6 atoms of Zr for every 1 atom of Hf in the dielectric film.

15. A method according to claim 8 wherein the dielectric film is used in a capacitor or transistor of memory or logic applications, or suitable combinations thereof.
